(19) United States
(12) Patent Application Publication
(10) Pub. No.: US 2017/0170109 A1
(43) Pub. Date: Jun. 15, 2017

(54) INTEGRATED CIRCUIT STRUCTURES WITH INTERPOSERS HAVING RECESSES

(71) Applicant: Intel Corporation, Santa Clara, CA (US)

(72) Inventors: KYU-OH LEE, Chandler, AZ (US); ISLAM A. SALAMA, Scottsdale, AZ (US)

(21) Appl. No.: 15/038,001

(22) PCT Filed: Jun. 25, 2015
(86) PCT No.: PCT/US2015/037808

§ 371 Date: May 19, 2016

(51) Int. Cl. H01L 23/498; H01L 23/66; H01L 21/48; H01L 23/00

(52) U.S. Cl. CPC H01L 23/49838; H01L 23/49822; H01L 23/49833; H01L 24/16; H01L 23/66; H01L 21/4857; H01L 21/4853; H01L 2224/16157; H01L 2224/16197; H01L 2924/1205; H01L 2223/6666

(57) ABSTRACT

Disclosed herein are integrated circuit (IC) structures having interposers with recesses. For example, an IC structure may include: an interposer having a resist surface; a recess disposed in the resist surface, wherein a bottom of the recess is surface-finished; and a plurality of conductive contacts located at the resist surface. Other embodiments may be disclosed and/or claimed.

### TECHNICAL FIELD

The present disclosure relates generally to the field of integrated circuits (ICs), and more particularly, to IC structures with interposers having recesses.

### BACKGROUND

In integrated circuits (ICs), interposers are sometimes used to reduce the footprint of integrated circuit devices. However, the height of conventional structures with interposers may be too great for small form factor settings, such as smartphones.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the FIGS. of the accompanying drawings.

FIG. 1 is a cross-sectional side view of a portion of an interposer, in accordance with various embodiments.

FIG. 2 is a cross-sectional side view of a portion of an Integrated circuit (IC) structure with a package on interposer structure, in accordance with various embodiments.

FIGS. 3-11 are cross-sectional side views of IC structures at various stages in a manufacturing sequence, in accordance with various embodiments.

FIG. 12 is a flow diagram of a method of manufacturing an interposer, in accordance with various embodiments.

FIG. 13 is a flow diagram of a method of manufacturing an IC structure with a package on interposer structure, in accordance with various embodiments.

FIG. 14 is a cross-sectional side view of a portion of an interposer, in accordance with various embodiments.

FIG. 15 is a cross-sectional side view of a portion of an IC structure with a package on interposer structure, in accordance with various embodiments.

FIG. 16 is a block diagram of an example computing device that may include one or more of any of the interposers and IC structures disclosed herein.

### DETAILED DESCRIPTION

Disclosed herein are integrated circuit (IC) structures with interposers having recesses, and related structures and methods. Various ones of the embodiments disclosed herein may enable IC structures wherein an interposer includes a recess such that one or more components of an IC package coupled to the interposer extend into the recess.

Interposer-based structures have been used to provide high-density logic (e.g., by stacking memory components) for small form factor devices, such as smartphones and tablet computers. In particular, an interposer may be used to couple an IC package to a motherboard or other component to reduce the footprint of a device. This may be referred to as a “package on interposer” or “patch on interposer” (PoINT) structure. An interposer may be manufactured using circuit board manufacturing techniques (e.g., subtractive processes), the cost of which may be substantially less than the cost to manufacture an IC package (e.g., using semi-additive processes).

Conventionally, an IC package may be coupled to an interposer with a mid-level interconnects (MLI) technique. Such a technique may include ball grid array (BGA) coupling. When high density is desired, the pitch between the BGA bumps may be less than 600 microns. This fine pitch between the IC package and the interposer has conventionally meant that the “MLI gap” between the IC package and the interposer is very small.

Although a small MLI gap may appear to be desirable for limiting the height of a device, conventional interposer-based structures have not been able to achieve reduced height without compromising power delivery performance. In particular, IC packages disposed on interposers often include a processing device (e.g., a processing core included in a central processing unit (CPU)) arranged such that the IC package is disposed between the processing device and the Interposer. When such an IC package including a processing device is disposed on an interposer, power must be delivered through the interposer to the processing device. Decoupling capacitors are conventionally arranged between a power source and its destination to reduce noise, but the small MLI gap between an interposer and the IC package has meant that it is not possible to include an adequately strong (and therefore large) decoupling capacitor between the interposer and the IC package. Some conventional approaches have positioned a decoupling capacitor “underneath” the interposer, between a motherboard and the interposer. However, the long path from such a decoupling capacitor through the interposer and through the IC package to the processing device generates and attracts noise that degrades the performance of the processing device. Other conventional approaches have used “low profile” capacitors secured to the IC package between the IC package and the interposer (to reduce the length of the path between the capacitor and the processing device), but the limited size of these capacitors (e.g., less than 200 microns in height) has meant that these capacitors have provided inadequate capacitance to achieve desired noise suppression. Indeed, low-profile capacitors may have a maximum capacitance that is half or less of the desired capacitance.

Various ones of the embodiments disclosed herein include a recess in an interposer to achieve a region of greater standoff height between the interposer and an IC package disposed thereon. A component of the IC package may extend into the recess in the interposer. This may allow such components to be physically closer to other components on the IC package than previously achievable without compromising the overall height of an interposer-based structure. For example, an adequately strong decoupling capacitor (e.g., having a capacitance of approximately 0.47 microfarads and a height greater than 200 microns) may be positioned on the “underside” of an IC package and may extend into a recess of an interposer on which the IC package is disposed. When a processing device is coupled to the “top side” of the IC package, the decoupling capacitor may be strong enough and close enough to the processing device to achieve desired performance without sacrificing the MLI density.

In the following detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “interposer” may refer to a component configured to be positioned between a circuit board (e.g., a motherboard) and a package. An interposer may be constructed using circuit board construction techniques (e.g., motherboard construction techniques).

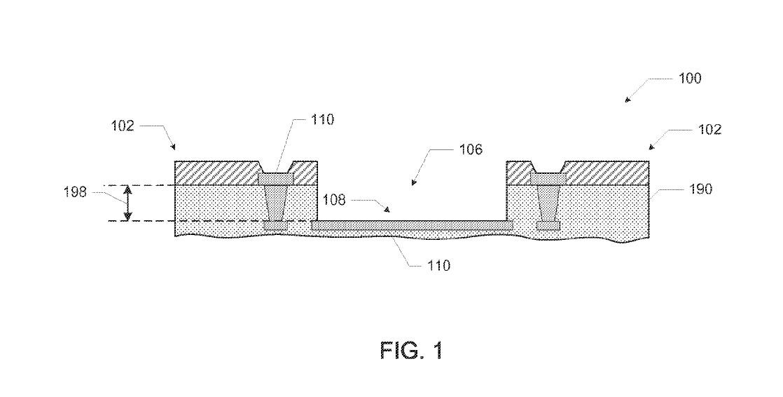

FIG. 1 is a cross-sectional side view of a portion of an interposer 100, in accordance with various embodiments. The interposer 100 may have a resist surface 102 and a recess 106 disposed in the resist surface 102. A bottom 108 of the recess 106 may be surface finished. In some embodiments, the bottom 108 of the recess 106 may be formed of a conductive material 112 that has been surface finished, such as mechanically polished copper. In some embodiments, surface finishing may include application of a nickel-palladium-gold (NiPdAu) finish or copper organic solderability preservative (CuOSP) finish. In some embodiments, the bottom 108 of the recess 106 may be formed of an insulative material, such as a solder resist, and may not include the conductive material 112.

One or more conductive contacts 110 may be located at the resist surface 102. The resist surface 102 may be formed on a build-up material 190, and may be patterned to expose the conductive contacts 110, in accordance with any suitable known technique. Any suitable build-up material may be used for the build-up materials discussed herein, such as Ajinomoto build-up film (ABF) and prepreg build-up film. The build-up material 190 may include further structures therein, such as vias, conductive contacts, other devices, or any other suitable electrical or insulative structure (some non-limiting examples of which are shown).

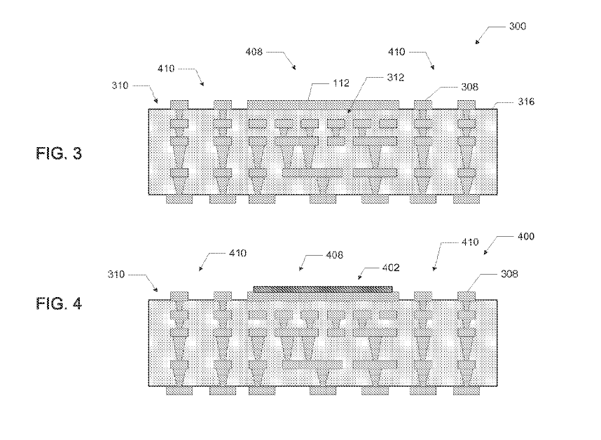

The recess 106 may have a depth 198 (measured between a “top” of the build-up material 190 below the resist surface 102 and a “top” of the build-up material 190 below the recess 106. The depth 198 of the recess 106 may take any suitable value (and as discussed below with reference to FIGS. 3-11, may be readily adjusted by changing the build-up thickness or the number of stack ups during manufacturing). For example, in some embodiments, the recess 106 may have a depth 198 between 50 microns and 300 microns.

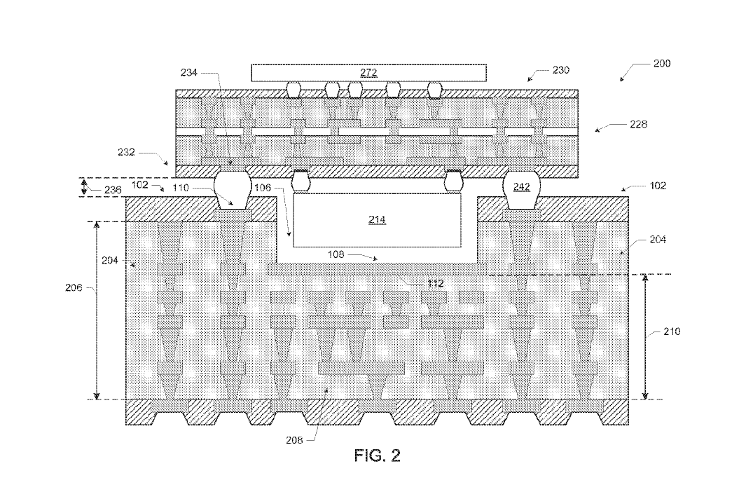

In some embodiments, at least two conductive contacts 110 may be located at the resist surface 102, and may be spaced apart by a distance of less than 600 microns (not illustrated in FIG. 1), although any suitable spacing may be used. One or more of the conductive contacts 110 may be formed from copper (e.g., as copper pads). In use, the interposer 100 may be coupled to a motherboard (not shown) positioned “below” the interposer 100. As discussed above, the interposer 100 may route electrical signals from the motherboard to other components coupled to the interposer 100 (e.g., IC packages coupled to the conductive contacts 110, as discussed below reference to FIG. 2).

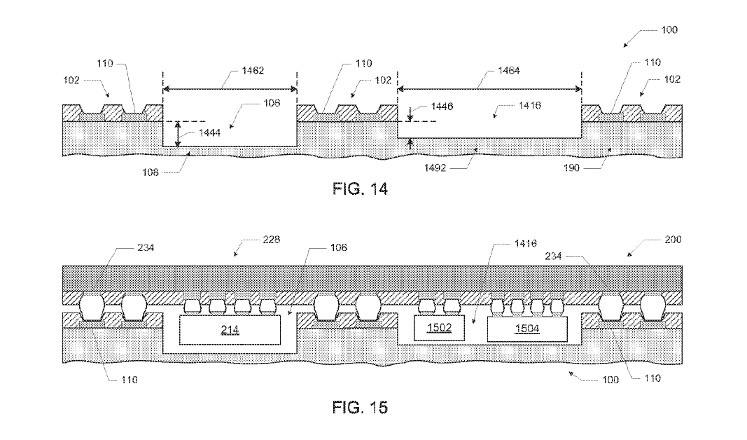

FIG. 2 is a cross-sectional side view of a portion of an IC structure 200 with a package on interposer structure, in accordance with various embodiments. The IC structure 200 may include an embodiment of the interposer 100, as illustrated. Although a particular number of IC packages and components are illustrated in FIG. 2, the techniques disclosed herein may be utilized to form an IC structure having fewer or more packages (e.g., disposed in recesses) as desired. Examples of some such embodiments are discussed below with reference to FIGS. 14-15.

As discussed above with reference to FIG. 1, the interposer 100 of FIG. 2 may have a resist surface 102 and a recess 106 disposed in the resist surface 102. A bottom 108 of the recess 106 may be surface finished. In the embodiment of the Interposer 100 of FIG. 2, a conductive material 112 is shown as disposed at the bottom 108 of the recess 106. The conductive material 112 may be included in embodiments in which a laser is used to “cut” out the recess 106, as discussed below with reference to FIG. 7, and may serve as a laser stop. In embodiments in which another technique is used to cut out the recess 106 (e.g., mechanical routing), the conductive material 112 may not be included.

The interposer 100 may include a first build-up portion 204 disposed under the resist surface 102. The first build-up portion 204 may have a thickness 206. The interposer 100 may include a second build-up portion 208 under the bottom 108 of the recess 106. The second build-up portion 208 may have a thickness 210. The thickness 206 may be greater than the thickness 210. As illustrated in FIG. 2, the first build-up portion 204 may include a number of electrical structures, such as vias and conductive pads, arranged therein and in electrical contact with the conductive contacts 110. The second build-up portion 208 may also include a number of electrical structures, such as vias and conductive pads, arranged therein.

The first build-up portion 204 and the second build-up portion 208 may be formed using a sequence of build-up deposition operations, as discussed below with reference to FIGS. 3-5. In particular, a first phase of build-up may provide the second build-up portion 208, while the first build-up portion 204 may be provided by a combination of the first phase of build-up and a second phase of build-up that follows the first phase of build-up.

The IC structure 200 of FIG. 2 includes an IC package 228. The IC package 228 may have a first surface 230, a second surface 232 disposed opposite the first surface 230, and one or more conductive contacts 234 located at the second surface 232. The IC package 228 may be any suitable IC package, and may have additional IC packages or other components disposed thereon (e.g., as discussed below). In particular, the IC package 228 may have a component 214 coupled to the second surface 232 of the IC package 228. The component 214 may be an active component (e.g., a component that relies on a source of energy) or a passive component (e.g., a component that does not introduce net energy into a circuit). An example of an active component may include radio frequency (RF) circuitry. In embodiments in which the component 214 is a passive component, the component 214 may include a capacitor, a resistor, an inductor, or any combination of components.

As illustrated in FIG. 2, the IC package 228 may be coupled to the interposer 100 so that the component 214 is disposed between the interposer 100 and the IC package 228. One or more of the conductive contacts 234 may be electrically coupled to a corresponding one or more of the conductive contacts 110, and the component 214 may extend into the recess 106. As illustrated in FIG. 2, in some embodiments, the component 214 may not be in physical contact with the interposer 100. In FIG. 2, the conductive contacts 234 are illustrated as coupled to the conductive contacts 110 via solder balls 242 disposed on the conductive contacts 110 of the resist surface 102 (e.g., in the apertures formed by the patterned resist surface 102).

The IC structure 200 of FIG. 2 also includes an IC component 272. The IC component 272 may be a bare die, for example, and/or may be any suitable IC component, such as a system on chip (SoC), an application processor, a central processing unit (CPU), or a process control hub (PCH). The IC component 272 may be located at the first surface 230 of the IC package 228. In some embodiments, the IC component 272 may include a processing core and the component 214 may be a decoupling capacitor for the processing core of the IC component 272. The second surface 232 of the IC package 228 may be spaced away from the resist surface 102 of the interposer 100 by a distance 236. In some embodiments, the distance 236 may be less than 250 microns.

As noted above, the depth of the recess 106 may take any suitable value. In particular, the depth of the recess 106 may be selected in view of the height of the component 214 that will extend into the recess 106 and/or the anticipated spacing between the interposer 100 and another IC package coupled to the conductive contacts 110 of the resist surface 102 (e.g., the IC package 228).

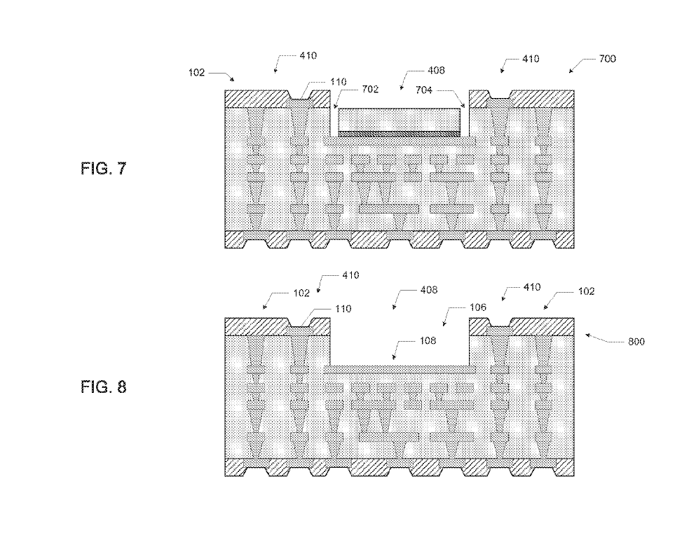

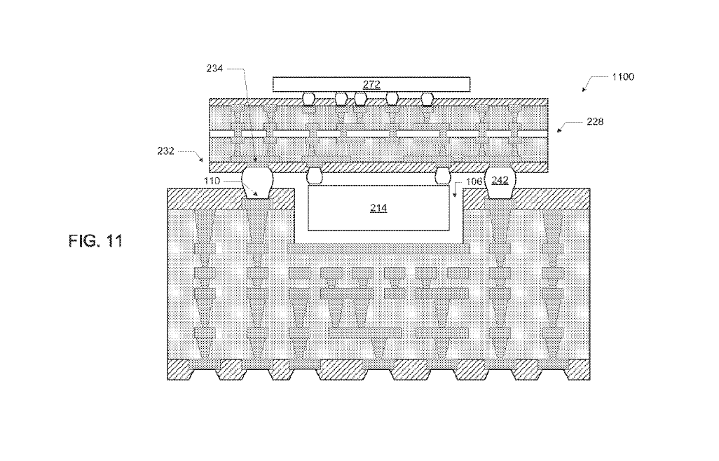

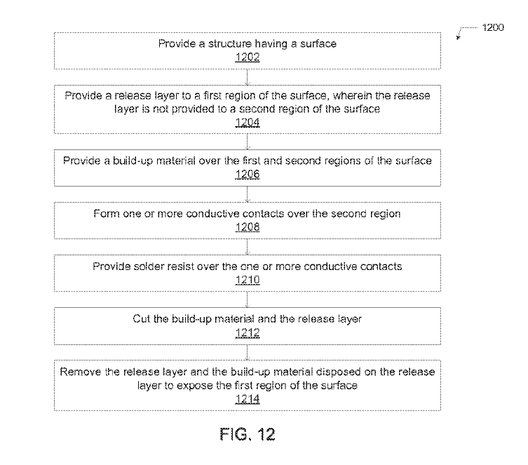

FIGS. 3-11 are cross-sectional side views of IC structures at various stages in a manufacturing sequence, in accordance with various embodiments. In particular, the manufacturing sequence illustrated by FIGS. 3-11 is shown as manufacturing the IC structure 200 of FIG. 2. However, this is simply illustrative, and the operations discussed below with reference to FIGS. 3-11 may be used to manufacture any suitable IC structure. Additionally, although the various manufacturing operations discussed below with reference to FIGS. 3-11 and the other methods disclosed herein are discussed in a particular order, the manufacturing operations may be performed in any suitable order. For example, operations related to cutting the build-up material and the release layer (e.g., as discussed below with reference to FIG. 7) may be performed before or after the formation of a resist surface (e.g., as discussed below with reference to FIG. 6). The manufacturing operations discussed below with reference to FIGS. 3-11 may also be performed at different times or in different facilities. For example, the operations discussed with reference to FIGS. 3-10 may be performed as part of a production sequence, while the operations discussed with reference to FIG. 11 may be performed separately as part of a structure sequence.

FIG. 3 illustrates a structure 300 including a build-up material 316 and electrical structures 312 arranged therein and thereon. In particular, the structure 300 may include a conductive material 112 disposed in a first region 408 at a surface 310 and one or more conductive contacts 308 disposed in a second region 410 at the surface 310. The conductive material 112 and the conductive contacts 308 may be formed of the same material (e.g., copper). The first region 408 and the second region 410 may be nonoverlapping on the surface 310. The structure 300 may be formed using any suitable conventional substrate build process.

FIG. 4 illustrates a structure 400 subsequent to providing a release layer 402 over the first region 408 of the structure 300. In particular, the release layer 402 may be provided on top of the conductive material 112 and may span at least some of the extent of the conductive material 112. In the structure 400, the conductive material 112 may be disposed between the release layer 402 and the build-up material 316. The release layer 402 may not be in contact with the conductive contacts 308 in the second region 410. In some embodiments, providing the release layer 402 may include paste printing the release layer 402. In other embodiments, providing the release layer 402 may include laminating the release layer 402. The material used for the release layer 402 may have weak adhesion to the conductive material 112 so that it can be readily removed in later manufacturing operations (e.g., as discussed below with reference to FIG. 8). Any suitable release material may be used for the release layers disclosed herein, such as epoxy, silicone or paraffin-based resins with carbon-based particles or fibers. The release material may have poor adhesion with build-up film (e.g., prepreg film) and copper.

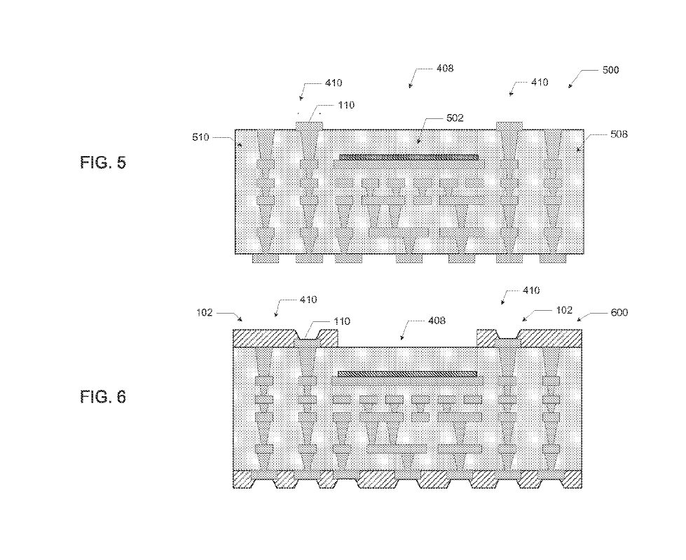

FIG. 5 illustrates a structure 500 subsequent to providing a build-up material to the structure 400 and forming additional conductive structures 510 and conductive contacts 110. In particular, the build-up material may include build-up material 502 provided over the first region 408 and build-up material 508 provided over the second region 410. Although the build-up material 502 and the build-up material 508 are separately identified, the build-up material 502 and the build-up material 508 may be provided in a continuous manufacturing operation. The build-up material 502 may be provided such that the release layer 402 is disposed between the build-up material 502 and the conductive material 112. The conductive structures 510 (e.g., conductive pads and vias) may be formed alternatingly with the provision of build-up material (e.g., by depositing build-up material, drilling out or otherwise removing a portion of the build-up material, forming the conductive structure, then repeating the process). The conductive contacts 110 may be formed over the second region 410. No conductive contacts or other conductive structures may be formed in or on the build-up material 502 disposed “above” the release layer 402.

FIG. 6 illustrates a structure 600 subsequent to forming the resist surface 102 on the structure 500. As discussed above with reference to FIGS. 1 and 2, the resist surface 102 may be patterned to expose the conductive contacts 110 over the second region 410. No solder resist may be applied over the first region 408.

FIG. 7 illustrates a structure 700 subsequent to cutting the build-up material 502 of the structure 600 over the first region 408 down to and including the release layer 402. In some embodiments, cutting the build-up material 502 may be performed by laser cutting the build-up material 502 at a boundary of the first region 408. In some embodiments, the laser energy used to cut the build-up material 502 down to the release layer 402 may cut through the release layer 402 and stop upon reaching the conductive material 112 (e.g., a hard metal, such as copper). The depth to which cutting can occur may depend on the power of the laser used to perform the cutting. In other embodiments, cutting the build-up material 502 may be performed by mechanically routing the build-up material 502 at a boundary of the first region. Note that FIG. 7 is a cross-sectional side view of a structure; when viewed from the “top,” the build-up material 502 may be cut to form any desired shape (e.g., a rectangle), and thereby to form a recess having any desired footprint, as discussed below.

FIG. 8 illustrates a structure 800 subsequent to removing the release layer 402 and the build-up material 502 disposed on the release layer 402 of the structure 700. When the edges of the release layer 402 are exposed after the laser cutting (as shown in FIG. 7), the release layer 402 may be mechanically lifted and “peeled” away from the conductive material 112, removing the build-up material 502 at the same time. When the release layer 402 and the build-up material 502 are removed, a recess 106 may be formed and the conductive material 112 may be exposed at the bottom 108 of the recess 106. The structure 800 may be an embodiment of the interposer 100 discussed above with reference to FIG. 1. In particular, the structure 800 may form an interposer having a resist surface 102, a recess 106, and one or more conductive contacts 110 located at the resist surface 102. The depth of the recess 106 is a function of the thickness of the build-up material 502 disposed on the release layer 402. Thus, the depth of the recess 106 may be set during manufacturing by adjusting the thickness of the build-up material deposited with each layer and/or the number of layers (e.g., the number of stack ups) formed after depositing the release layer 402.

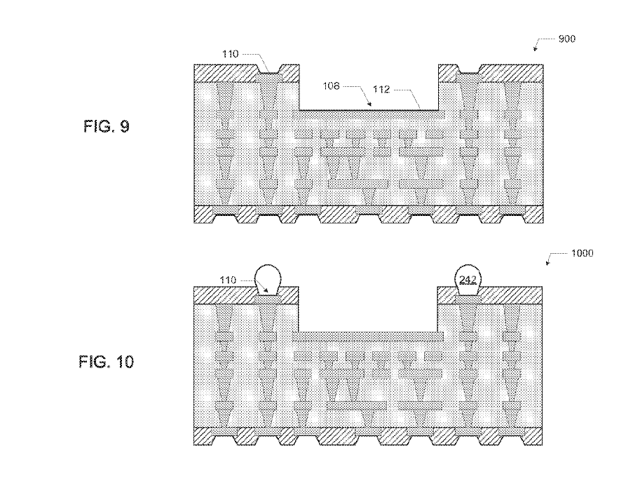

FIG. 9 illustrates a structure 900 subsequent to surface finishing the structure 800. In some embodiments, surface finishing the structure 800 may include mechanically polishing appropriate portions of the structure 900, in accordance with known techniques. In some embodiments, surface finishing may include applying a finish material, such as NiPdAu or CuOSP. In particular, the exposed surfaces of the conductive contacts 110 and the conductive material 112 may be surface finished. Other portions of the structure 900 may be surface finished as well (e.g., the second-level interconnects (SU) on the “bottom” of the structure 900). The structure 900 may be an embodiment of the interposer 100 discussed above with reference to FIG. 1. In particular, the structure 900 may form an interposer having a resist surface 102, a recess 106 having a bottom 108 that is surface finished, and one or more conductive contacts 110 located at the resist surface 102.

FIG. 10 illustrates a structure 1000 subsequent to providing solder balls 242 to the conductive contacts 110 at the resist surface 102. The solder balls 242 may be provided using conventional techniques, such as ball grid array (BGA) attachment. The structure 1000 may be an embodiment of the interposer 100 discussed above with reference to FIG. 1. In particular, the structure 1000 may form an interposer having a resist surface 102, a recess 106 having a bottom 108 that is surface finished, and one or more conductive contacts 110 located at the resist surface 102.

FIG. 11 illustrates a structure 1100 subsequent to coupling an IC package 228 to the structure 1000 via the solder balls 242. The IC package 228 may include conductive contacts 234 that are electrically coupled to the conductive contacts 110 via the solder balls 242. The structure 1000 may take the form of any of the embodiments of the IC structure 200 discussed above with reference to FIG. 2. The structure 1000 may also be an embodiment of the interposer 100 discussed above with reference to FIG. 1. In particular, the structure 1000 may form an interposer having a resist surface 102, a recess 106 having a bottom 108 that is surface finished, and one or more conductive contacts 110 located at the resist surface 102. The IC package 228 may be pre-assembled before coupling the IC package 228 to the structure 1000.

FIG. 12 is a flow diagram of a method 1200 of manufacturing an interposer, in accordance with various embodiments. Although operations of the method 1200 may be discussed with reference to the interposer 100 and components thereof, this is simply for illustrative purposes and the method 1200 may be utilized to form any suitable IC structure.

At 1202, a structure may be provided (e.g., the structure 300 of FIG. 3). The structure may have a surface having a first region and a second region (e.g., the first region 408 and the second region 410 of the surface 310 of FIG. 3). The first region and the second region may be nonoverlapping, and one or more conductive contacts may be located at the surface in the second region (e.g., the one or more conductive contacts 308 of FIG. 3). A conductive material may be located at the surface in the first region (e.g., the conductive material 112 of FIG. 3).

At 1204, a release layer may be provided to the first region of the surface (e.g., the release layer 402 of the structure 400 of FIG. 4). In some embodiments, the release layer may be provided over a conductive material in the first region of the surface (e.g., the conductive material 112). In some embodiments, 1204 may include paste printing the release layer. In some embodiments, 1204 may include laminating the release layer.

At 1206, a build-up material may be provided to the first and second regions (e.g., the build-up material 502 and 508 of the first region 408 and the second region 410, respectively, of the structure 500 of FIG. 5).

At 1208, one or more conductive contacts may be formed over the second region (e.g., the conductive contacts 110 of the structure 500 of FIG. 5).

At 1210, solder resist may be provided over the one or more conductive contacts (e.g., as illustrated in forming the resist surface 102 of the structure 600 of FIG. 6).

At 1212, the build-up material may be cut to the release layer (e.g., cut to the release layer 402 as illustrated with reference to the structure 700 of FIG. 7). In some embodiments, 1212 may include laser cutting or mechanically routing the build-up material at a boundary of the first region.

At 1214, the release layer and the build-up material disposed on the release layer may be removed to expose the first region of the surface (e.g., to expose the conductive material 112, as discussed above with reference to the structure 800 of FIG. 8).

In some embodiments, the method 1200 may also include, after providing the build-up material at 1206 and before cutting the build-up material at 1212, forming one or more conductive vias in the build-up material in the second region (e.g., as discussed above with reference to FIG. 5). In some such embodiments, the method 1200 may also include providing solder balls to the conductive contacts formed at 1208. In some embodiments, the method 1200 may include surface finishing a bottom of the recess. Surface finishing may include mechanical polishing and/or applying a NiPdAU or CuOSP finish.

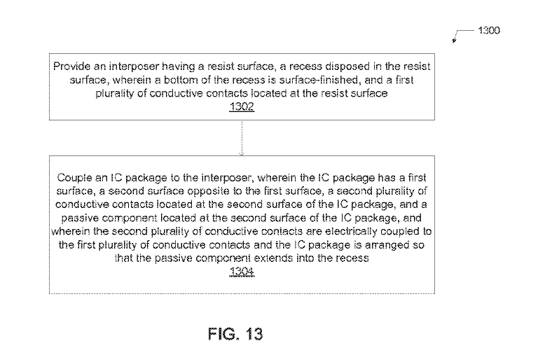

FIG. 13 is a flow diagram of a method 1300 of manufacturing an IC structure, in accordance with various embodiments. Although operations of the method 1300 may be discussed with reference to the IC structure 200 and components thereof, this is simply for illustrative purposes and the method 1300 may be utilized to form any suitable IC structure.

At 1302, an interposer may be provided (e.g., the interposer 100 of FIG. 1). The interposer provided at 1302 may have a resist surface; a recess disposed in the resist surface, wherein a bottom of the recess is surface finished; and a first plurality of conductive contacts located at the resist surface (e.g., the recess 106 disposed in the resist surface 102 and the first plurality of conductive contacts 110).

At 1304, an IC package may be coupled to the interposer (e.g., the IC package 228 coupled to the interposer 100 of FIG. 2). The IC package may have a first surface, a second surface, a second plurality of conductive contacts located at the second surface of the IC package, and a component located at the second surface of the IC package (e.g., the first surface 230, the second surface 232, the conductive contacts 234, and the component 214 of FIG. 2). The component may be a passive component, such as a capacitor. The second plurality of conductive contacts may be electrically coupled to the first plurality of conductive contacts, and the IC package may be arranged so that the component extends into the recess.

Various embodiments of the interposers disclosed herein may include multiple recesses into which components may extend. For example, FIG. 14 is a cross-sectional side view of a portion of an interposer 100, in accordance with various embodiments. The interposer 100 of FIG. 14, like the interposer 100 of FIG. 1, may have a resist surface 102 and a recess 106 disposed in the resist surface 102. The recess 106 may have a bottom 108. In some embodiments, the bottom 108 may be surface finished. One or more conductive contacts 110 may be located at the resist surface 102. The resist surface 102 may be formed on a build-up material 190, and may be patterned to expose the conductive contacts 110 in accordance with any suitable known technique. The build-up material 190 may include further structures therein, such as vias, conductive contacts, other devices, or any other suitable electrical or insulative structure (not shown for ease of illustration).

Additionally, the interposer 100 may include an additional recess 1416 disposed in the resist surface 102. The recess 1416 may have a bottom 1492. In some embodiments, the bottom 1492 may be surface finished. The recess 106 may have a depth 1444 and the recess 1416 may have a depth 1446. In some embodiments, the depth 1444 and the depth 1446 may be different. For example, as illustrated in FIG. 14, the depth 1446 may be less than the depth 1444. The recess 106 may have a width 1462 and the recess 1416 may have a width 1464. In some embodiments, the width 1462 and the width 1464 may be different. For example, as illustrated in FIG. 14, the width 1462 may be less than the width 1464. The recesses, resist surfaces, and conductive contacts of the interposer 100 of FIG. 14 may take the form of any of the embodiments of the interposer 100 disclosed herein.

Various embodiments of the IC structures disclosed herein may include IC structures including interposers with multiple recesses and/or multiple components extending into a single recess. For example, FIG. 15 is a cross-sectional side view of a portion of an embodiment of the IC structure 200, in accordance with various embodiments. The IC structure 200 of FIG. 15 may, like the IC structure 200 of FIG. 2, include an embodiment of the interposer 100 (as illustrated, the interposer 100 of FIG. 14).

The IC structure 200 of FIG. 15 includes conductive contacts 234 of an IC package 228 electrically coupled to conductive contacts 110 of the interposer 100. The IC package 228 includes a component 214 secured to the IC package 228 such that the component 214 extends into the recess 106 (e.g., in accordance with any of the embodiments discussed above with reference to FIG. 2).

The IC structure 200 of FIG. 15 also includes components 1502 and 1504 secured to the IC package 228 such that the components 1502 and 1504 extend into the recess 1416. The components 1502 and 1504 may be adjacent to each other in the recess 1416 (e.g., in accordance with any of the embodiments discussed above with reference to FIG. 2). As illustrated in FIG. 15, in some embodiments, the components 214, 1502, and 1504 may not be in physical contact with the interposer 100.

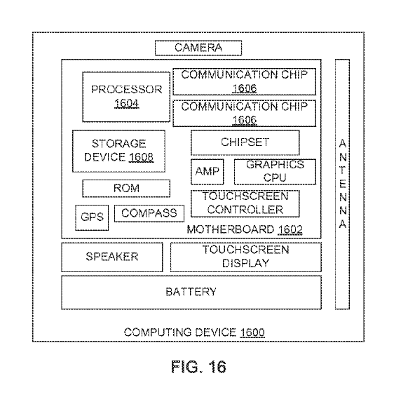

Embodiments of the present disclosure may be implemented into a system using any interposers, IC packages, or IC package structures that may benefit from the recessed conductive contacts and manufacturing techniques disclosed herein. FIG. 16 schematically illustrates a computing device 1600, in accordance with some implementations, which may include interposers having recesses formed in accordance with any of the embodiments disclosed herein. For example, the interposer 100, or the IC structure 200, may be configured to include a storage device 1608, a processor 1604, or a communication chip 1606 of the computing device 1600 (discussed below).

The computing device 1600 may be, for example, a mobile communication device or a desktop or rack-based computing device. The computing device 1600 may house a board such as a motherboard 1602. The motherboard 1602 may include a number of components, including (but not limited to) a processor 1604 and at least one communication chip 1606. Any of the components discussed herein with reference to the computing device 1600 may be arranged in an interposer-based structure in accordance with the techniques disclosed herein. In further implementations, the communication chip 1606 may be part of the processor 1604.

The computing device 1600 may include a storage device 1608. In some embodiments, the storage device 1608 may include one or more solid state drives. Examples of storage devices that may be included in the storage device 1608 include volatile memory (e.g., dynamic random access memory (DRAM)), non-volatile memory (e.g., read-only memory, ROM), flash memory, and mass storage devices (such as hard disk drives, compact discs (CDs), digital versatile discs (DVDs), and so forth).

Depending on its applications, the computing device 1600 may include other components that may or may not be physically and electrically coupled to the motherboard 1602. These other components may include, but are not limited to, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, and a camera.

The communication chip 1606 and the antenna may enable wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1606 may implement any of a number of wireless standards or protocols, including but not limited to Institute for Electrical and Electronic Engineers (IEEE) standards inducing Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible broadband wide region (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1606 may operate in accordance with a Global System for Mobile Communications (GSM), General Packet Radio Service (GPRS), Universal Mobile Telecommunications System (UMTS), High Speed Packet Access (HSPA), Evolved HSPA (E-HSPA), or LTE network. The communication chip 1606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 1606 may operate in accordance with other wireless protocols in other embodiments.

The computing device 1600 may include a plurality of communication chips 1606. For instance, a first communication chip 1606 may be dedicated to shorter range wireless communications such as Wi-Fi and Bluetooth, and a second communication chip 1606 may be dedicated to longer range wireless communications such as GPS, EDGE, GPRS, CDMA, WIMAX, LTE, EV-DO, and others. In some embodiments, the communication chip 1606 may support wired communications. For example, the computing device 1600 may include one or more wired servers.

The processor 1604 and/or the communication chip 1606 of the computing device 1600 may include one or more dies or other components in an IC package. Such an IC package may be coupled with an interposer or another package using any of the techniques disclosed herein (e.g., using the recess structures disclosed herein). The term “processor” may refer to any device or portion of a device that processes electronic data from registers and/or memory to transform that electronic data into other electronic data that may be stored in registers and/or memory.

In various implementations, the computing device 1600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1600 may be any other electronic device that processes data. In some embodiments, the recessed conductive contacts disclosed herein may be implemented in a high-performance computing device.

The following paragraphs provide examples of the embodiments disclosed herein.

Example 1 is an IC structure, including: an interposer having a resist surface; a recess disposed in the resist surface, wherein a bottom of the recess is surface-finished; and a plurality of conductive contacts located at the resist surface.

Example 2 may include the subject matter of Example 1, and may further specify that the plurality of conductive contacts is a first plurality of conductive contacts, and the IC structure further includes an IC package having a first surface, a second surface opposite to the first surface, a second plurality of conductive contacts located at the second surface of the IC package, and a component coupled to the second surface of the IC package; wherein the second plurality of conductive contacts are electrically coupled to the first plurality of conductive contacts and the IC package is arranged so that the component extends into the recess.

Example 3 may include the subject matter of Example 2, and may further specify that the component is a capacitor having a capacitance greater than 0.5 microfarads.

Example 4 may include the subject matter of any of Examples 2-3, and may further specify that the component has a height that is greater than 200 microns.

Example 5 may include the subject matter of any of Examples 2-4, and may further specify that the IC package has a processing core located at the first surface of the IC package and the component is a decoupling capacitor for the processing core.

Example 6 may include the subject matter of any of Examples 2-5, and may further specify that a distance between the second surface of the IC package and the resist surface is less than 250 microns.

Example 7 may include the subject matter of any of Examples 2-6, and may further include a solder material in physical contact with one of the first plurality of conductive contacts and also in physical contact with one of the second plurality of conductive contacts.

Example 8 may include the subject matter of any of Examples 2-7, and may further specify that the component is not in physical contact with the interposer.

Example 9 may include the subject matter of any of Examples 1-8, and may further specify that the recess has a depth greater than 100 microns.

Example 10 may include the subject matter of any of Examples 1-9, and may further specify that the plurality of conductive contacts comprises a plurality of copper pads.

Example 11 may include the subject matter of any of Examples 1-10, and may further specify that the interposer is coreless.

Example 12 is a method of manufacturing an Interposer, including: providing a structure having a surface; providing a release layer to a first region of the surface, wherein the release layer is not provided to a second region of the first surface; after providing the release layer, providing a build-up material over the first and second regions of the surface; forming a plurality of conductive contacts over the second region; providing solder resist over the plurality of conductive contacts; cutting the build-up material and the release layer; and removing the release layer and the build-up material disposed on the release layer to expose the first region of the surface.

Example 13 may include the subject matter of Example 12, and may further specify that providing the release layer comprises paste printing the release layer.

Example 14 may include the subject matter of any of Examples 12-13, and may further specify that providing the release layer comprises laminating the release layer.

Example 15 may include the subject matter of any of Examples 12-14, and may further specify that cutting the build-up material and the release layer comprises laser cutting the build-up material and the release layer at a boundary of the first region.

Example 16 may include the subject matter of any of Examples 12-15, and may further include, after providing the build-up material and before cutting the build-up material and the release layer, forming a plurality of conductive vias in the build-up material over the second region.

Example 17 may include the subject matter of any of Examples 12-16, and may further include providing solder material to the plurality of conductive contacts.

Example 18 may include the subject matter of any of Examples 12-17, and may further specify that the first region of the surface does not include any conductive contacts.

Example 19 is a method of manufacturing an IC structure, including: providing an interposer, wherein the interposer includes a resist surface, a recess disposed in the resist surface, wherein a bottom of the recess is surface-finished, and a first plurality of conductive contacts located at the resist surface; and coupling an integrated circuit (IC) package to the interposer, wherein the IC package has a first surface, a second surface opposite to the first surface, a second plurality of conductive contacts located at the second surface of the IC package, and a component located at the second surface of the IC package, and wherein the second plurality of conductive contacts are electrically coupled to the first plurality of conductive contacts and the IC package is arranged so that the component extends into the recess.

Example 20 may include the subject matter of Example 19, and may further specify that the IC package includes a processing device located at the first surface of the IC package.

Example 21 may include the subject matter of any of Examples 19-20, and may further specify that the recess has a depth between 50 microns and 300 microns.

Example 22 may include the subject matter of any of Examples 19-21, and may further specify that the component is a capacitor having a capacitance greater than 0.5 microfarads.

Example 23 may include the subject matter of any of Examples 19-22, and may further specify that the component has a height that is greater than 200 microns.

Example 24 may include the subject matter of any of Examples 19-23, and may further specify that the IC package has a processing core located at the first surface of the IC package and the component is a decoupling capacitor for the processing core.

Example 25 may include the subject matter of any of Examples 19-24, and may further include, as part of coupling the IC package to the interposer, providing a solder material in physical contact with one of the first plurality of conductive contacts and also in physical contact with one of the second plurality of conductive contacts.

1-25. (canceled)

26. An integrated circuit (IC) structure, comprising:
an interposer having a resist surface;
a recess disposed in the resist surface, wherein a bottom of the recess is surface-finished; and
a plurality of conductive contacts located at the resist surface.

27. The IC structure of claim 26, wherein the plurality of conductive contacts is a first plurality of conductive contacts, and wherein the IC structure further comprises:
an IC package having a first surface, a second surface opposite to the first surface, a second plurality of conductive contacts located at the second surface of the IC package, and a component coupled to the second surface of the IC package;
wherein the second plurality of conductive contacts are electrically coupled to the first plurality of conductive contacts and the IC package is arranged so that the component extends into the recess.

28. The IC structure of claim 27, wherein the component is a capacitor having a capacitance greater than 0.5 microfarads.

29. The IC structure of claim 27, wherein the component has a height that is greater than 200 microns.

30. The IC structure of claim 27, wherein the IC package has a processing core located at the first surface of the IC package and the component is a decoupling capacitor for the processing core.

31. The IC structure of claim 27, wherein a distance between the second surface of the IC package and the resist surface is less than 250 microns.

32. The IC structure of claim 27, further comprising:
a solder material in physical contact with one of the first plurality of conductive contacts and also in physical contact with one of the second plurality of conductive contacts.

33. The IC structure of claim 27, wherein the component is not in physical contact with the interposer.

34. The IC structure of claim 26, wherein the recess has a depth greater than 100 microns.

35. The IC structure of claim 26, wherein the plurality of conductive contacts comprises a plurality of copper pads.

36. The IC structure of claim 26, wherein the interposer is coreless.

37. A method of manufacturing an interposer, comprising:
providing a structure having a surface;
providing a release layer to a first region of the surface, wherein the release layer is not provided to a second region of the first surface;
after providing the release layer, providing a build-up material over the first and second regions of the surface;
forming a plurality of conductive contacts over the second region;
providing solder resist over the plurality of conductive contacts;
cutting the build-up material and the release layer; and
removing the release layer and the build-up material disposed on the release layer to expose the first region of the surface.

38. The method of claim 37, wherein providing the release layer comprises paste printing the release layer.

39. The method of claim 37, wherein providing the release layer comprises laminating the release layer.

40. The method of claim 37, wherein cutting the build-up material and the release layer comprises laser cutting the build-up material and the release layer at a boundary of the first region.

41. The method of claim 37, further comprising, after providing the build-up material and before cutting the build-up material and the release layer, forming a plurality of conductive vias in the build-up material over the second region.

42. The method of claim 37, further comprising providing solder material to the plurality of conductive contacts.

43. The method of claim 37, wherein the first region of the surface does not include any conductive contacts.

44. A method of manufacturing an integrated circuit (IC) structure, comprising:
providing an interposer, wherein the interposer includes:
a resist surface,
a recess disposed in the resist surface, wherein a bottom of the recess is surface-finished, and
a first plurality of conductive contacts located at the resist surface; and
coupling an integrated circuit (IC) package to the interposer, wherein the IC package has a first surface, a second surface opposite to the first surface, a second plurality of conductive contacts located at the second surface of the IC package, and a component located at the second surface of the IC package, and wherein the second plurality of conductive contacts are electrically coupled to the first plurality of conductive contacts and the IC package is arranged so that the component extends into the recess.

45. The method of claim 44, wherein the IC package includes a processing device located at the first surface of the IC package.

46. The method of claim 44, wherein the recess has a depth between 50 microns and 300 microns.

47. The method of claim 44, wherein the component is a capacitor having a capacitance greater than 0.5 microfarads.

48. The method of claim 44, wherein the component has a height that is greater than 200 microns.

49. The method of claim 44, wherein the IC package has a processing core located at the first surface of the IC package and the component is a decoupling capacitor for the processing core.

50. The method of claim 44, further comprising, as part of coupling the IC package to the interposer, providing a solder material in physical contact with one of the first plurality of conductive contacts and also in physical contact with one of the second plurality of conductive contacts.
